(19) United States
(12) Patent Application Publication
(10) Pub. No.: US 2026/0171836 A1
(43) Pub. Date: Jun. 18, 2026

(54) A POWER DISTRIBUTION UNIT (PDU) FOR OPTIMIZING THE DISTRIBUTION OF POWER TO MULTI-PSU ICT EQUIPMENT SUCH AS SERVERS AND NETWORK SWITCHES ARRANGED IN A DATA CENTER RACK

(71) Applicant: ETHERNETICS, Lierde (BE)

(72) Inventor: Robert Leune, Sint-Amandsberg (BE)

(21) Appl. No.: 19/127,094

(22) PCT Filed: Nov. 28, 2023
(86) PCT No.: PCT/EP2023/083436

§ 371 Date: May 2, 2025

(30) Foreign Application Priority Data
Nov. 28, 2022 (BE) 2022/5963

(51) Int. Cl. H02J 9/06; G06F 1/28; G06F 1/30; G06F 11/30; H01R 13/66; H01R 13/70; H01R 25/00; H05K 5/02

(52) U.S. Cl. CPC H02J 9/062; G06F 1/28; G06F 1/30; G06F 11/3058; H01R 13/6675; H01R 13/6683; H01R 13/70; H01R 25/003; G06F 2200/261; H05K 5/0247

(57) ABSTRACT

A power distribution unit (PDU) is provided for distributing power to electrical equipment such as servers and network switches arranged in a data center rack. The PDU module comprises a three-phase switch and a decoupling switch and is configured to be in connection with a controller. The PDU module may also comprise a controller. Further a computer-implemented method is provided for distributing three-phase power in a rack system wherein the rack system comprises a power distribution system for powering electrical equipment and configured to be fed with a three-phase power source. The computer-implemented method is controlling the imbalance between the three live lines.

### CROSS-REFERENCE TO RELATED APPLICATIONS

This application is a National Phase Patent Application and claims priority to and the benefit of International Patent Application No. PCT/EP2023/083436, filed on Nov. 28, 2023, which claims priority to and the benefit of Belgian Patent Application No. 2022/5963, filed on Nov. 28, 2022. The entire contents of both of which are incorporated herein by reference.

### TECHNICAL FIELD

The present invention relates to a Power Distribution Unit (PDU) module, to a power bar comprising one or more PDU modules, to a power distribution system comprising multiple power bars. The invention further relates to the use of the above-mentioned elements.

### BACKGROUND OF THE INVENTION

Centralized data centers for servers, network switches and other information and communication technology (ICT) equipment have been in use for a number of years. Typical centralized data centers contain numerous racks of ICT equipment that require power. A Power Distribution Unit (PDU) is a device typically used to distribute power from a power source input to ICT equipment stored in the rack.

The existing PDU implementations however provide sub-optimal power consumption and typically introduce cybersecurity flaws.

Racks today have multi-PSU (PSU stands for Power Supply Unit) servers. The distribution of power towards these multi-PSU servers is also distributed sub-optimal resulting in sub-optimal power consumption of the racks. A power distribution system with a three-phase inlet and hard-wired single-phase outlets inherently introduces current imbalance to the power distribution grid of the computer room. Imbalance between the phases leads to stranded capacity, both in terms of power and ICT. Furthermore, imbalance introduces upstream heat losses in the cabling all the way up to the uninterruptible power supply (UPS). The UPS will also heat up more as it has to compensate for the imbalance introduced on rack level. Furthermore, taking into consideration that the load imbalance shifts over time with changing IT workloads, there is need for improvement that takes this shift over time with changing IT workloads into account.

Therefore, based on the above, there is thus a need for a new technology wherein power consumption can be optimized and wherein cybersecurity flaws are limited.

### DESCRIPTION OF THE INVENTION

To that end, the present invention provides multiple enhancements over the prior art.

In an embodiment of the present invention, a computer-implemented method for distributing three-phase power in a rack system is provide wherein the rack system comprises a power distribution system for powering electrical equipment and is configured to be fed with a three-phase power source, the power distribution system comprising at least one power bar comprising at least three outlets, power sensors for measuring the voltage and current of each outlet, and phase switches for switching the live lines of the outlets, the method comprising
receiving the voltage and current value of each outlet,
calculating the power of each outlet based on the received voltage and current values,
registering the calculated power for each outlet and the corresponding phase setting,
calculating the power load imbalance based on the calculated power and the phase setting of each outlet resulting in a calculated load imbalance,
calculating individual power calculations at each outlet through an iterative process, in which the load imbalance is calculated for hypothetical combinations of phase settings,
selecting the hypothetical combination with the lowest load imbalance as Best Case,
comparing the load imbalance of Best Case with the calculated load imbalance, and
if the load imbalance of Best Case is lower than the calculated load imbalance, sending instructions to the phase switches to set the phase settings to the phase settings of Best Case.

By equalizing power consumption over the three phases, the power headroom is maximized and stranded capacity is eliminated. At the same time, upstream heat losses are reduced.

In an embodiment of the invention, a power distribution system is provided comprising a processor configured to perform the imbalance correction method.

In an embodiment of the invention, a computer program is provided comprising instructions which, when the program is executed by a computer, cause the computer to carry out the steps of the imbalance correction method.

In an embodiment of the invention, a further computer-implemented method is provided for distributing power in a rack system wherein the rack system comprises a power distribution system for powering multi-PSU electrical equipment and is fed with at least two power sources, the power distribution system comprising at least two power bars comprising at least one outlet, power sensors for measuring the voltage and current signals of each outlet, and decoupling switches for switching the live line towards an outlet on or off, the method comprising
receiving the voltage and current signals of each outlet,
applying power quality measurements on the received signals to determine triggers for a power fail,
if a trigger for a power fail is determined for an outlet connected to a multi-PSU equipment, determining another outlet connected to the multi-PSU equipment, and
transmitting an instruction to the other outlet to switch the decoupling switch to the on status.

In an embodiment of the invention, a power distribution system is provided comprising a processor configured to perform the power fail correction method described above.

In an embodiment of the invention, a computer program is provided comprising instructions which, when the program is executed by a computer, cause the computer to carry out the steps of the power fail correction method.

In an embodiment of the invention, a power distribution system is provided that overcomes drawbacks in the prior art.

An advantage of this system is that this system is capable of switching over complete outlet modules or individual outlets from phase to phase. For example, C13 modules may switch over all outlets of the module while C19 modules may switch over individual outlets of the module.

This system also has the advantage that the controller may be configured to execute a load imbalance correction.

Foremost, this system has the advantage that it provides dynamic load redistribution capabilities on ICT equipment level.

In an embodiment of the invention, a PDU module is provided that comprises:
an input configured to be coupled to a power source to receive 3-phase power from the power source;
a plurality of power lines coupled to the input, the power lines being configured to carry the 3-phase power;
multiple outlets each one coupled to two of the plurality of power lines such as to receive power from one of the three phases of the 3-phase power, each outlet being configured to be coupled to an electrical equipment such as to power the electrical equipment. Preferably, each outlet is provided with an power sensor configured to sense a parameter of the power supplied to said outlet. The sensed parameter can be used to adapt the power delivered to the outlet.

The PDU module comprises a controller coupled to the power sensors.

In an embodiment, the PDU module further comprises a data connector configured to receive data from external devices such as other PDU modules coupled to the same power source. In an alternative embodiment as will be described below, multiple PDU modules can be plugged into a power bar. In this case, the data connector could be coupled to some or all of the PDU modules. The data connector could for example be provided in a dedicated gateway module plugged into one power bar and it could for example be configured to receive data from external devices such as PDU modules provided on another power bar coupled to another power source.

In an embodiment, the PDU module further comprises the controller. In a preferred alternative embodiment as will be described below, multiple PDU modules can be assembled into a power bar. In this case, the controller could be centralized for some or all of the PDU modules. The controller could for example be provided in a dedicated gateway module provided in the power bar, for example the same gateway module that comprises the centralized data connector.

According to a first improvement of the present invention, the PDU module comprises the features of claim 2. The PDU module therefore further comprises at least one phase switch configured to selectively couple each outlet to two of the power lines such as to select the phase delivered to said outlet. Preferably, the three-phase power lines comprise a neutral line and three live lines. Preferably only the live lines are switched by the phase switch, i.e. the neutral line is not switched. This for example enables to provide a PDU module which is operated in wye configuration (as opposed to delta configuration) with the outlet operating voltage being taken between a live line and the neutral line.

According to an embodiment of the present invention, the phase switch is further configured to selectively decouple the outlet from the power lines. To that end, preferably the phase switch comprises a switching part and a decoupling part. The switching part performs the above mentioned switching between power lines. The decoupling part interrupts the power lines. This enables to implement a “break before make” arrangement, which enables to perform “live switching”.

According to an embodiment of the present invention, one phase switch is provided for each outlet such as to select the phase delivered to each outlet. Alternatives are however also possible. One phase switch could for example be provided for a group of outlets such as to select the phase delivered to the group of outlets. The group of outlets are for example all the outlets on the PDU module. Alternatively for example, only the switching part could be common to the group of outlets and each outlet could for example be provided with its own decoupling part.

According to an embodiment of the present invention, the parameter measured by the power sensor of the outlet is indicative of the load on the outlet, further referred to as the load parameter. Preferably the load parameter is the current drawn by the outlet. Preferably, the controller is configured to monitor the load parameters of the outlets within the PDU module and further configured to operate the at least one phase switch based on the monitored load parameters. Preferably the controller determines based on the load parameters, the total loads on each of the phases, and wherein the controller is further configured to operate the at least one phase switch such as to improve the load balance of the three phases. Improving the load balance of the three phases has many advantages. One advantage is particularly present when the PDU is provided with power from the power source by intermediary of an Uninterruptible Power Supply (UPS), in which case a load imbalance continuously charges the UPS with the lesser loaded phase and discharges the UPS with the more loaded phase. Preferably, the controller maintains a list of outlets, the phase delivered to said outlets and the load parameter of the outlets, and wherein the controller uses the list to determine which outlets should switch phase and wherein the controller operates the phase switch accordingly. Preferably, the controller determines the highest loaded phase and the lesser loaded phases, and uses the list to determine which outlets should switch from the highest loaded phase to one of the lesser loaded phases. Preferably, the list further comprises the priority of the outlets indicating the importance of reliable operation of the outlets. The controller is preferably arranged to switch those outlets with higher priority status to more stable phases. According to an embodiment of the present invention, the controller is configured to receive via the data connector, phase loading information related to the loading of the three phases of at least one external device coupled to the same power source, and is further configured to operate the at least one phase switch additionally based on the received phase loading information. Preferably, the external device coupled to the power source is another PDU module coupled to the same power source. This embodiment is particularly advantageous when dealing with a power bar comprising multiple PDU modules as will be explained further below.

According to a second improvement of the present invention, the PDU module, for example of the first improvement of the present invention as explained above, comprises the features of claim 13. In the second improvement, the power sensor is enabled to sample the load parameter at microsecond level, and the controller is adapted to enable oscilloscope view graphical representation of the parameter in time domain and/or frequency domain. The representation preferably comprises representation of the parameter's harmonics.

According to an embodiment of the present invention, the controller is arranged to identify abnormalities in the time domain and/or frequency domain representation of the parameter. This embodiment implements a failure prediction system. The failure prediction system uses reference oscilloscope view graphical representations of a correctly functioning PSU (Power Supply Unit) of the electrical equipment, and compares those references with the real-time oscilloscope view graphical representation of the parameter. If the differences between those representations become significant, or when they evolve rapidly, this can be an indicator of electrical equipment wear or PDU module wear. The above mentioned reference oscilloscope view graphical representations could for example be a snapshot that is taken at entering into service of the electrical equipment or PDU module, or could for example be taken from a library of known electrical equipment and PDU modules. The comparison can be done for example by means of machine learning.

According to an embodiment of the present invention, the controller is arranged to compare the measured parameters to reference data retrieved from a cloud where the measured parameters of the PDU module and preferably from other PDU modules are stored such as to allow to identify abnormalities in the time domain and/or frequency domain representation of the parameter for example based on machine learning.

According to an embodiment of the present invention, the parameter measured by the power sensor is the current delivered to the outlet. According to an embodiment of the present invention, the input of the PDU module further comprises a voltage sensor arranged to measure the voltages between the power lines at microsecond level, and wherein the controller is adapted to enable oscilloscope view graphical representation of the voltages in time domain and/or frequency domain preferably comprising representation of the parameter's harmonics, i.e. mutatis mutandis to the analysis performed based on the above mentioned power sensor.

According to an aspect of the present invention, the PDU module, for example of the first and/or second improvement of the present invention as explained above, comprises the features of claim 17, i.e. it is integrated into a power bar. The power bar comprises an elongated frame arranged to be mounted to a data center rack in a 0 U or 1 U configuration. Preferably it is mounted vertically in a 0 U configuration. The frame is also referred to as the “backbone”. The power bar comprises at least one PDU module as described above mounted on the frame. The power bar allows PDU modules to be releasably mounted on the frame in a modular manner, for example enabling the exchange of a PDU module comprising C19 outlets with a PDU module comprising C13 outlets. According to an embodiment of the present invention, the controller and/or the data connector is/are mounted on the power bar, for example in a releasable manner. Preferably, the power bar comprises a data connector and/or a controller common for all the PDU modules in the power bar. The centralized data connector and centralized controller are preferably provided in a dedicated gateway module. The gateway module is preferably releasably mounted on the frame in a modular manner. Preferably, the gateway module has ports for connecting to environmental sensors such as temperature and humidity sensors. The environmental sensors provides the controller with information regarding the environmental conditions within the data center. These conditions for example could influence the oscilloscope view graphical representation of the load parameter, and is thus preferably taken into account upon comparing the graphical representation with a reference.

According to an embodiment of the present invention, the power bar further comprises at least one network switch module having a plurality of network ports, the at least one network switch module being releasably mounted on the frame. The modularity of the power bar thus extends beyond the capability of releasably receiving one or more PDU modules, and preferably extends into releasably receiving network switch modules. According to an embodiment of the present invention, the power bar comprises multiple PDU modules. According to an embodiment of the present invention, the frame comprises a power inlet connected to the power source. The modules mounted to the frame, i.e. those modules as described above, receive power from the power inlet.

According to an embodiment of the present invention, the frame comprises a power bus. The modules mounted on the frame connect to the power bus such as to transfer power from the power bus to the modules. Preferably, the modules can be inserted into the frame upon which the power contacts of the modules automatically make contact with the power bus.

According to an embodiment of the present invention, the frame comprises a data bus over which the modules can exchange data. Preferably the data bus communication is an ethernet communication. This allows the modules to communicate in a peer-to-peer manner, as opposed to a master-slave manner. Preferably, the modules can be inserted into the power bar upon which the data contacts of the modules automatically make contact with the data bus.

According to a further improvement of the present invention, power consumption reduction by tightly coupling a power distribution system is provided, comprising a first power bar as described above arranged to couple a set of electrical equipment to a first 3-phase power source, and a second power bar as described above arranged to couple the same set of electrical equipment to a second 3-phase power source, wherein the set of electrical equipment comprises two physically distinct power inlets wherein the first power inlet is connected to the first 3-phase power source and the second power inlet is connected to the second 3-phase power source. The present redundant power delivery system is thus a plural feed system for example a dual feed system, wherein the rack is provided with multiple, for example two, independent power sources and wherein the electrical equipment has plural, for example two, power inlets each one serviced by a separate power bar. This plural feed system ensures that the electrical equipment is provided with power substantially all the time, but it introduces superfluous power consumption, since some electrical circuits are implemented in multiples to provide redundancy, at the same time running too weakly loaded resulting in even higher inefficiencies.

According to an embodiment of the present invention, the system comprises a power switching controller arranged to switch between powering an electrical equipment of the set of electrical equipment with the outlet provided on the first power bar and the outlet provided on the second power bar. Preferably, the switching comprises dividing the power delivery to the electrical equipment between the outlet provided on the first power bar and the outlet provided on the second power bar according to a division scheme. Preferably the division scheme comprises powering the electrical equipment fully by the outlet provided on one of the first power bar (referred to as a primary outlet) and disabling the outlet on the second power bar. This embodiment ensures that a minimal amount of power is consumed by said electrical equipment. This of course leads to a redundancy risk, which can be controlled by providing a fast switching from a failed outlet to a working outlet on another power bar. An embodiment thus comprises switching to powering the electrical equipment fully by the outlet of the other one of the first power bar and the second power bar, referred to as a back-up outlet, upon detecting the failure of the primary outlet.

In an embodiment all the outlets of the first power bar are primary outlets and all of the outlets of the second power bar are back-up outlets. In order to ensure a very fast switching, the first power bar and the second power bar are directly connected by means of a data connector, preferably a data cable, such as to increase the speed by which the power switching controller can switch the outlets powering the electrical equipment. This avoids having to transmit a signal from the first power bar to the second power bar over an external network route. By not going over an external network route, cybersecurity is simultaneously increased.

According to an embodiment of the present invention, the power switching controller is provided in one of the first power bar or the second power bar, i.e. not in both the first power bar and the second power bar. This results in a cheaper redundant power delivery system. Preferably, the power switching controller is provided in the gateway module of the power bar. For maximum switching speed, the switching controller is implemented in the PDU module containing the primary outlet. This controller monitors the power parameters at microsecond level, continuously checking time and frequency domain measurements, including harmonics, and alerts the PDU module containing the back-up outlet in a peer-to-peer fashion when detecting abnormalities.

It is a further object of the present invention to provide a data center rack comprising at least one power bar as described above, in which at least one PDU module as described above is mounted, or at least one redundant power delivery system as described above.

It is a further object of the present invention to provide a method comprising the use of the PDU module as described above, or of the power bar as described above, of the power distribution system as described above, or of the data center rack as described above.

### BRIEF DESCRIPTION OF THE DRAWINGS

The invention will be further elucidated by means of the following description and the appended figures.

FIG. 1 is a perspective view of a power bar according to an embodiment of the present invention.

FIG. 2 shows the power bar from FIG. 1 with the modules removed from the frame.

FIG. 3A shows the frame profile of the frame of the power bar shown in FIGS. 1 and 2.

FIG. 3B shows the cross section of a frame profile according to an embodiment of the invention.

FIG. 4A is a schematic view of the wiring of a PDU module according to an embodiment of the present invention.

FIG. 4B is an alternative wiring of a PDU module according to an embodiment of the invention.

FIG. 4C is a further alternative wiring of a PDU module according to an embodiment of the invention.

FIGS. 5A, 5B, 5C, 5D, 5E, 5F show a graphical representation of load parameters in time domain for respectively a reference, healthy PSU (Power Supply Unit) and a faulty PSU.

FIG. 6 is a schematic view of a power distribution system according to an embodiment of the present invention.

FIG. 7 illustrates a flow chart of a load imbalance algorithm that may be executed by the controller 17 of the power distribution system 60

FIG. 8 shows an exploded view of a frame of a power bar.

FIG. 9 shows a PDU module in perspective view.

FIG. 10 illustrates a two-PSU server in 4 different statuses of the decoupling switches.

FIG. 11 illustrates the power consumption of a two-PSU server over a period of 48 hours controlled by an algorithm according to an embodiment of the invention.

FIG. 12 illustrates the efficiency of a PSU on the Y-axis of the graph for each percentage of load on the x-axis.

FIGS. 13, 14 and 15 illustrate the difference in heat loss between a traditional system without imbalance correction and a system according to embodiments of the invention with imbalance correction.

FIGS. 16, 17, 18 and 19 illustrate a computer-implemented method for failure checking according to an embodiment of the invention.

FIG. 20 illustrates the detection of a deviation of the expected zero-crossing time of the voltage curve over time.

### BRIEF DESCRIPTION OF THE FIGURES AND MODES FOR CARRYING OUT THE INVENTION

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. The dimensions and the relative dimensions do not necessarily correspond to actual reductions to practice of the invention.

Furthermore, the terms first, second, third and the like in the description and in the claims, are used for distinguishing between similar elements and not necessarily for describing a sequential or chronological order. The terms are interchangeable under appropriate circumstances and the embodiments of the invention can operate in other sequences than described or illustrated herein.

Moreover, the terms top, bottom, over, under and the like in the description and the claims are used for descriptive purposes and not necessarily for describing relative positions. The terms so used are interchangeable under appropriate circumstances and the embodiments of the invention described herein can operate in other orientations than described or illustrated herein.

Furthermore, the various embodiments, although referred to as “preferred” are to be construed as exemplary manners in which the invention may be implemented rather than as limiting the scope of the invention.

The term “comprising”, used in the claims, should not be interpreted as being restricted to the elements or steps listed thereafter; it does not exclude other elements or steps. It needs to be interpreted as specifying the presence of the stated features, integers, steps or components as referred to, but does not preclude the presence or addition of one or more other features, integers, steps or components, or groups thereof. Thus, the scope of the expression “a device comprising A and B” should not be limited to devices consisting only of components A and B, rather with respect to the present invention, the only enumerated components of the device are A and B, and further the claim should be interpreted as including equivalents of those components.

Further, in the context of this description, the terms “imbalance” and “unbalance” are used as equivalent terms with the same meaning.

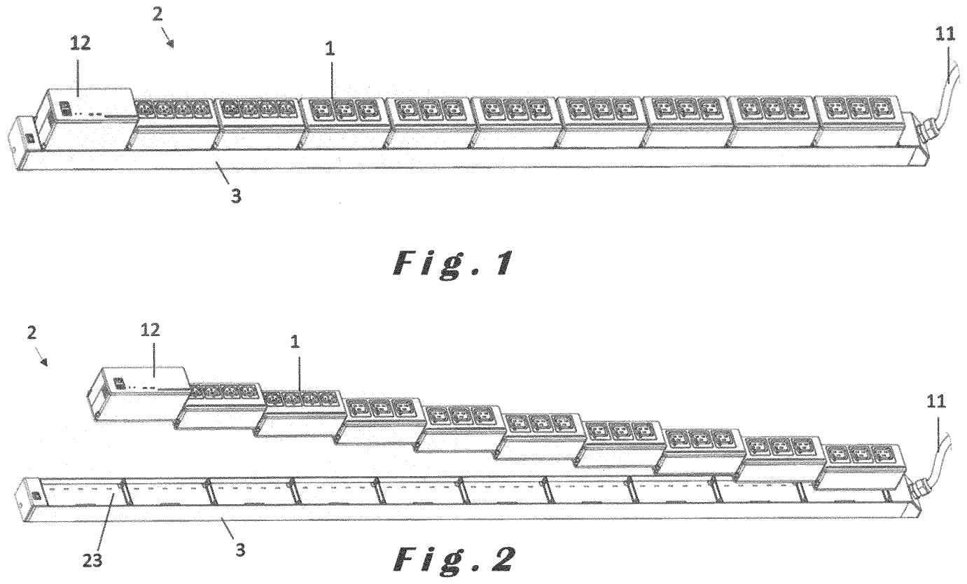

FIGS. 1 to 3 show a power bar 2. The power bar comprises an elongated frame 3 arranged to be mounted to a data center rack in a 0 U configuration (0 U is equivalent to ‘not mounted in the slots reserved for 19″ rack-mountable devices and thus no units U of the 19″ rack are used). The frame 3 is also referred to as the “backbone”. The power bar comprises multiple PDU modules 1 mounted on the frame 3.

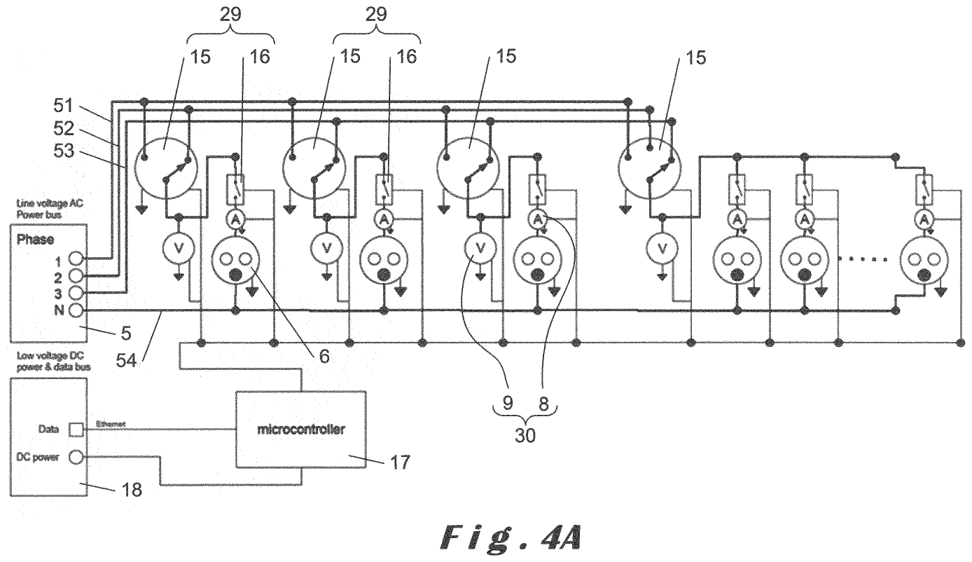

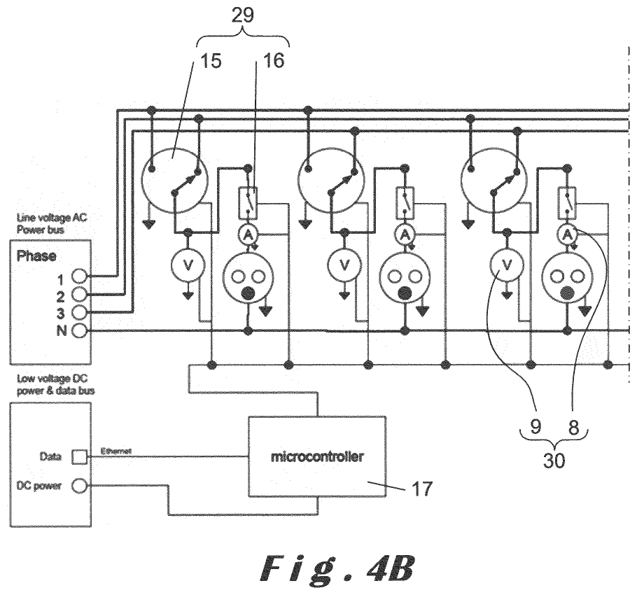

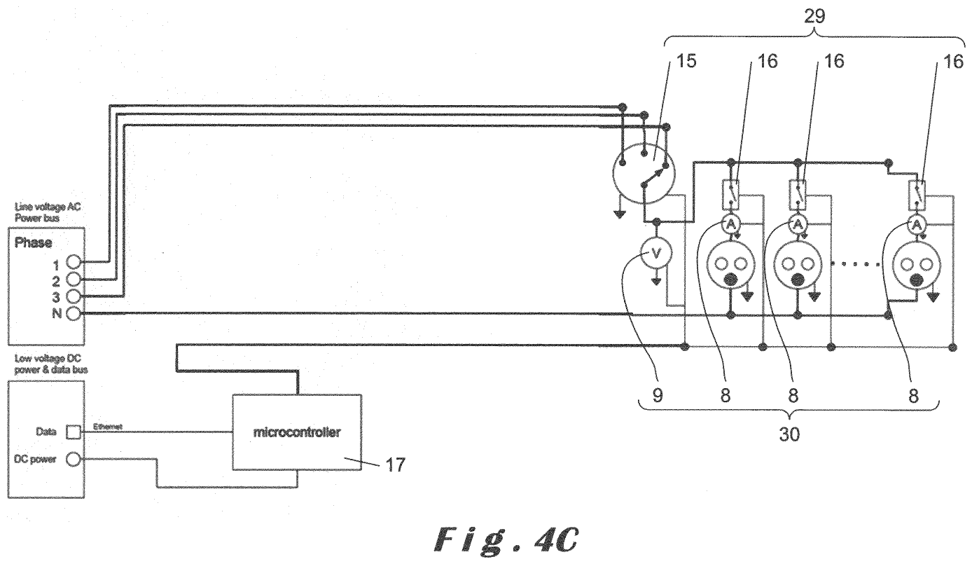

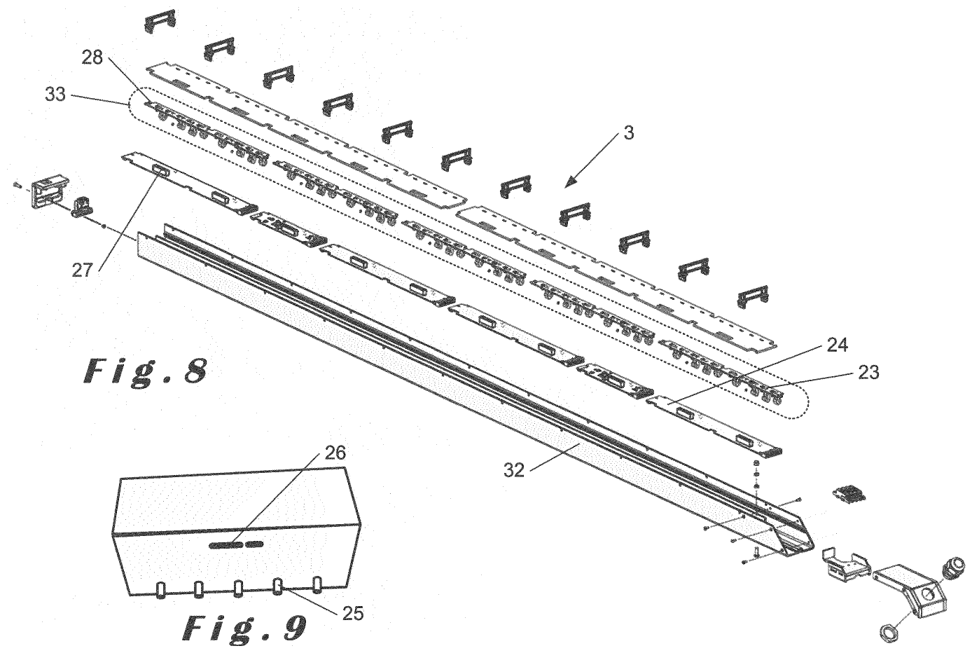

As specifically shown in FIG. 4A, the PDU modules 1 each comprise an input 5 configured to be coupled to a power source to receive 3-phase power from the power source. A plurality of power lines (51, 52, 53, 54) is coupled to the input 5 and the power lines (51, 52, 53, 54) are configured to carry the 3-phase power. The power lines are three live lines (51, 52, 53) and one neutral line 54. Multiple outlets 6 are coupled to two of the plurality of power lines such as to receive power from one of the three phases of the 3-phase power. In the embodiment of FIG. 4A, the outlets 6 are coupled to one of the three live lines (51, 52, 53) and the neutral line 54. Each outlet 6 is configured to be coupled to an electrical equipment, for example a server as shown in FIG. 6, such as to power said electrical equipment. Each outlet 6 is provided with a power sensor 30 configured to sense a parameter of the power supplied to the at least one outlet 6. The sensed parameter can be used to adapt the power delivered to the outlet 6. The power sensor 30 may comprise a current sensor 8, a voltage sensor 9, or both. The PDU modules 1 are also comprising a micro-controller 17 coupled to the power sensors 8, 9. The micro-controller 17 is further connected to a data port 18 which is configured to be connected to a second controller 22 via a data connection. In particular, the controller 22 is centralized for all of the PDU modules 1 and is provided in a dedicated gateway module 12 which may be a separate module attached to the frame 3 as shown in the FIGS. 1 and 2. As shown in FIG. 2, the power bar is modular, allowing PDU modules 1 to be releasably mounted on the frame 3 in a modular manner, for example enabling the exchange of a PDU module 1 comprising C19 outlets with a PDU module comprising C13 outlets. Furthermore, the gateway module 12 may also be releasably mounted on the frame in a modular manner. In an alternative embodiment, the gateway module is not modular but assembled on the frame. In still a further alternative embodiment, the processor 22 may be provided in a PDU module or in the frame. The frame 3 of the embodiment of FIGS. 1 and 2 comprises a power inlet 11 connected to or configured to be connected to the power source 11. The modules 1, 12 mounted to the frame 3, i.e. those modules as described above, receive power from the power inlet 11 when they are positioned and releasably mounted on the frame 3. The frame 3 comprises a power. Alternatively, as illustrated in FIG. 8, the frame 3 comprises a number of power contacts printed circuit boards 28 (PCBs) connected to the power source and comprising pin contact receivers 23 to receive pin contacts 25 part of the PDU module 1. The pin contacts 25 are illustrated on FIG. 9. The power contacts PCBs 28 are connected with each other to form a power bus 33. The frame 3 comprises further a number of data PCBs 24 comprising a data connector receiver 27 configured to connect with a mating data connector 26 which is part of the module 1. The mating data connecter 26 is illustrated on FIG. 9. When the PDU module 1 is correctly mounted, the pin contacts 25 of the PDU module 1 are connected to the pin contact receivers 23 and the data connector 26 of the PDU module 1 is connected to the data connector receiver 27 of the PCB boards.

The modules 1 mounted on the frame 3 connect to the power bus 33 such as to transfer power from the power bus 33 to the modules. The power bus 33 may comprise a series of printed circuit boards 28 configured to connect with the PDU modules 1 when these are releasably mounted to the frame 3. As is particularly shown in FIG. 2, the modules 1 can be mounted onto the frame 3 upon which the power contacts 25 of the modules 1 automatically make contact with the power bus 33.

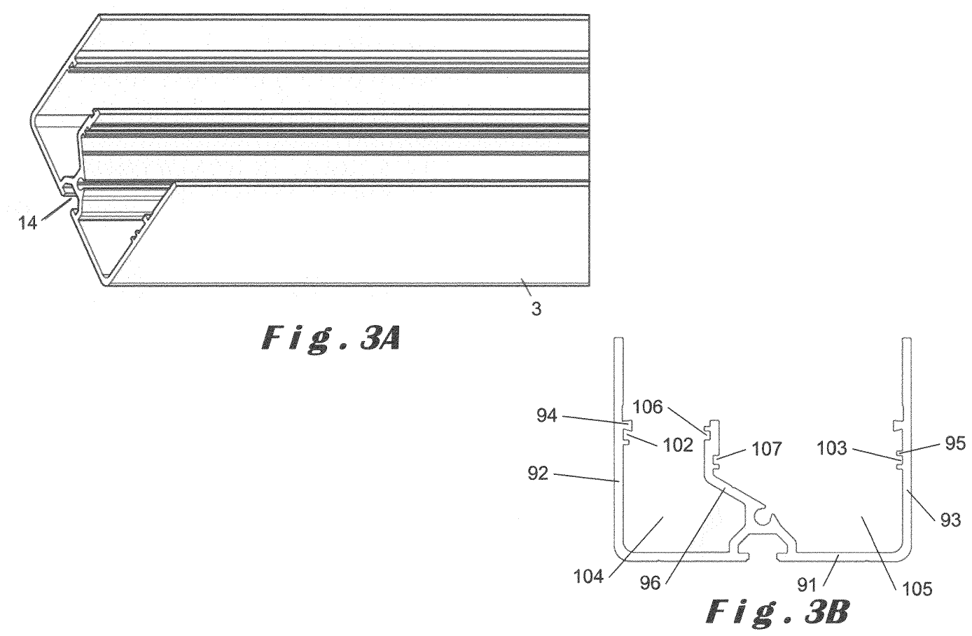

FIG. 3A shows a frame profile 32 which is part of the frame 3 of the power bar 2. The frame profile 32 comprises an elongated groove 14 arranged to mount the frame 3 to the data center rack. By providing a groove 14, as opposed to an element which penetrates the frame such as a screw, the risk of short circuiting is reduced.

An alternative structure of the frame for a power bar according to an embodiment of the invention is shown in FIG. 8. The frame 3 of FIG. 8 according to an embodiment of the invention, comprises a frame profile 32 with a specific cross section. The cross section of the frame profile 32 is shown in more detail in FIG. 3B. The frame profile 32 has a base wall 91 to which two outer side walls 92, 93 are upstanding to form a substantially U-shape. Each outer side wall 92, 93 has at the inside of the U-shape two upstanding walls 94, 95 forming a U-shaped groove 102, 103 on each outer side wall. The frame profile 32 also comprises a separation wall 96. The separation wall 96 comprises at each side a groove 106, 107 opposite to the grooves in the outer walls. Groove 106 in the separation wall 96 is opposite to groove 102 in the outer wall 92. These two grooves 106 and 102 are positioned and dimensioned such to receive the power contacts PCBs 28. Groove 107 in the separation wall 96 is opposite to groove 103 in the outer wall 93. These two grooves 107 and 103 are positioned and dimensioned such to receive the data PCBs 24. The separation wall 96 separates a power section 104 from a data section 105. This avoids that the data signals are disturbed by the power lines, the power bar or the power connections.

FIG. 4A is a schematic view of a wiring of an embodiment of the PDU module within the power bar 2 shown in the FIGS. 1 to 3. The PDU module 1 comprises multiple phase switches 29 configured to selectively couple each outlet 6 to two of the power lines (51, 52, 53, 54) such as to select the phase delivered to said outlet 6. In particular, the three-phase power lines comprise a neutral line 54 and three live lines 51, 52, 53, wherein only the live lines are switched by the phase switch 29, i.e. the neutral line 54 is not switched as illustrated in the embodiment of FIG. 4A. The phase switches 29 are further configured to selectively decouple the outlet from the power lines. To that end, the phase switches 29 comprise a switching part 15 and a decoupling part 16. A switching part of a phase switch 29 is in the context of this application also referenced as a three-phase switch 15. A decoupling part of a phase switch 29 is in the context of this application also referenced as a decoupling switch 16. The switching part 15 performs the above-mentioned switching between the live lines 51, 52, 53. The decoupling part 16 interrupts the live lines. This enables to implement a “break before make” arrangement, which enables to perform “live switching”. In the embodiment of FIG. 4A, the decoupling switch 16 is positioned between the output contact of the three-phase switch 15 and the outlet 6. In alternative embodiments, the position of the decoupling part 16 with respect to the switching part 15 can be different. The decoupling part 16 can in an embodiment be positioned before the switching part 15. For the first three outlets 6 starting from the left in FIG. 4A, one phase switch 29, each comprising a switching part 16 and a decoupling part 15 is provided for each outlet 6 such as to select the live line, if any, delivered to each outlet 6. For the last three outlets 6 from the right in FIG. 4A, one phase switch 29 is provided for the group of outlets 6 such as to select the phase delivered to the group of outlets 6. Each one of the three last outlets 6 from the right however comprises a separate decoupling part 16 such that the phase switch comprises in this configuration one switching part 15 and three decoupling parts 15, i.e. one switching part 15 for a group of outlets and a number of decoupling parts 15 corresponding to the amount of outlets in the group. As is shown in FIG. 4A, the power sensor 30 comprises a voltage sensor 9 and a current sensor 8 for each outlet of the first three outlets on the left. For the last three outlets from the right in FIG. 4A, the power sensor 30 comprises a current sensor 8 for each of the outlets 6 and a voltage sensor 9 which is common to all three of the outlets 6. The controller 17 is configured to monitor the load parameters of the outlets 6 within the PDU module 1, i.e. the voltage from the voltage sensor 9 and the current of the current sensor 8, and is further configured to operate the at least one phase switch 29 based on the monitored load parameters. The controller 17 may also determine, based on the load parameters, the total loads on each phase, and is further configured to operate the at least one phase switch such as to improve the load balance of the three phases, i.e. making the load on the three phases as equal as possible. FIG. 4B illustrates an alternative wiring of a PDU module wherein each out let has a three-phase switch 15 and a decoupling switch 16. In FIG. 4B, also each outlet 6 has a voltage senor 9 and a current sensor 8. FIG. 4C illustrates still another wiring of a PDU module wherein there is only one three-phase switch 15 and a decoupling switch 16 for each outlet. In FIG. 4C, there is one voltage sensor 9 for all outlet and there is one current sensor 8 for each outlet 6.

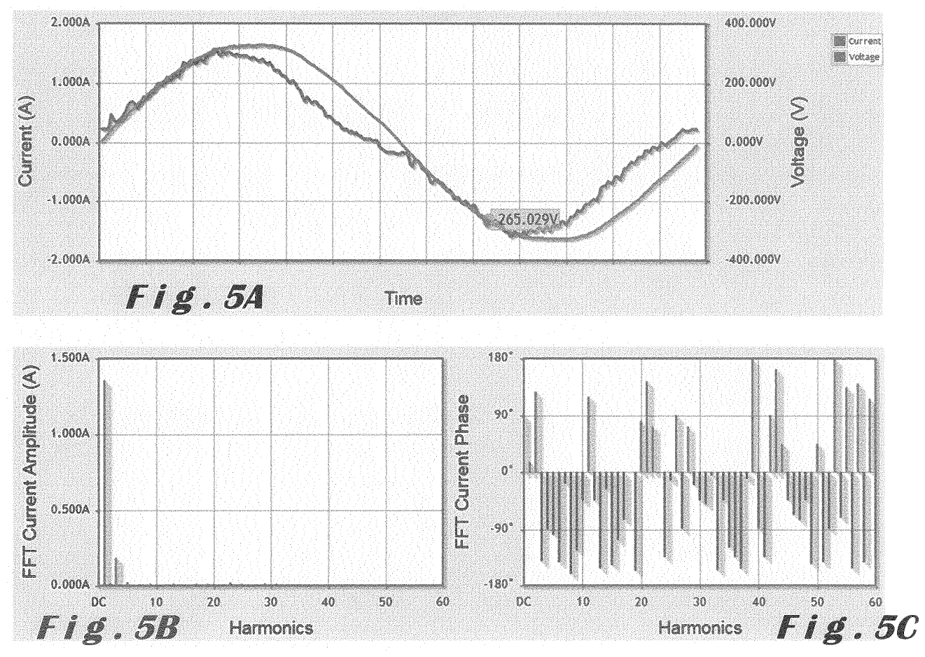

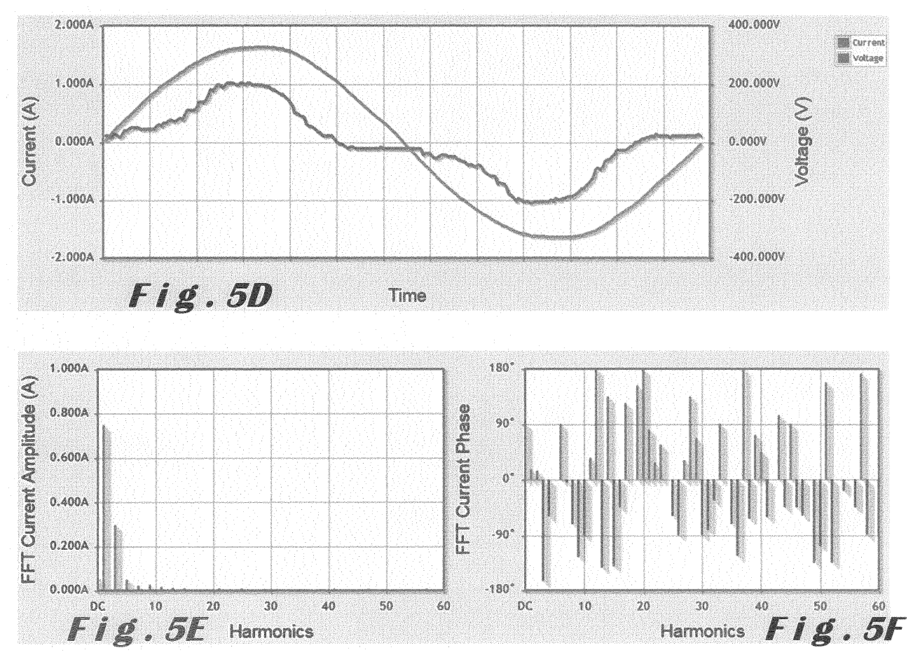

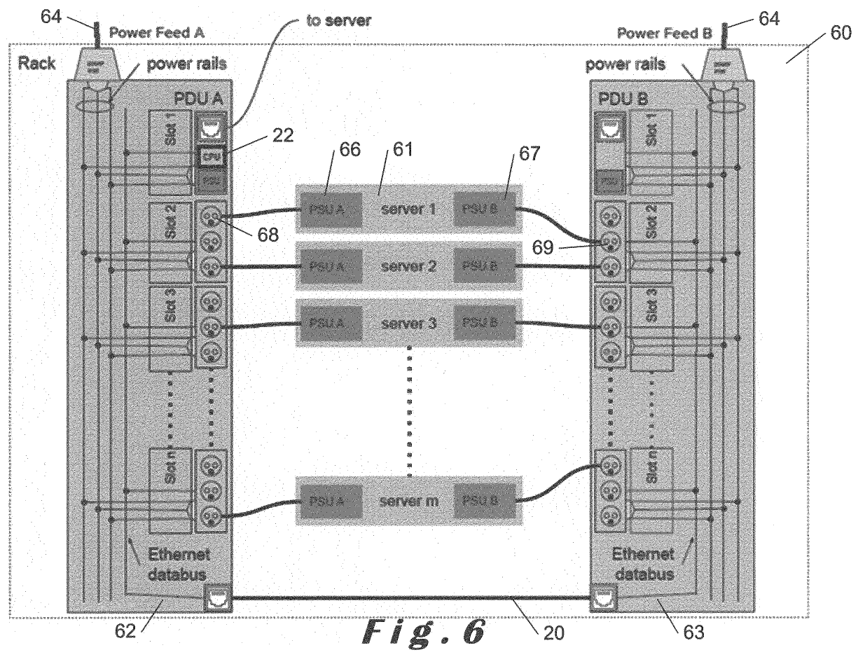

FIGS. 5A, 5B, 5C, 5D, 5E, 5F show a graphical representation of load parameters in time domain for respectively a reference, healthy PSU (Power Supply Unit) and a faulty PSU. The micro-controller 17 is arranged to detect differences between the graphical representations and to determine malfunction from the detected differences. FIG. 5A illustrates a healthy current and voltage curve over time. FIG. 5D illustrates a faulty current curve in the same time domain. FIGS. 5B and 5C are illustrating harmonics of the current for a healthy PSU. FIG. 5B illustrates the current amplitude. FIG. 5C illustrates the current phase. Illustrations of the same graphical representation of a faulty PSU are illustrated in FIG. 5E for the current amplitude and in FIG. 5F for the current phase. The controller 17 is configured to detect differences between such graphical representations.

FIG. 6 illustrates a power distribution system 60 according to an embodiment of the invention for powering multi-PSU, PSU standing for power supply unit, devices 61 in a rack system. The power distribution system 60 comprises two power bars 62, 63 respectively referred to as PDU A and PDU B, each one having slots for receiving the modules. In an embodiment, the power bars 62, 63 are the power bars of FIGS. 1 and 2. Each power bar comprises a power feed 64, 65. The power feeds 64, 65 provide power to the outlets. A first function of the embodiment of FIG. 6 is to operate as a redundant power distribution system. The redundant power distribution system comprises the first power bar 62 (PDU A) arranged to couple a set of electrical equipment 61 to a first 3-phase power source 64 through a first PSU 66 of the electrical equipment, and the second power bar 63 (PDU B) arranged to couple the same set of electrical equipment 61 to a second 3-phase power source through a second PSU 67. If one of the two power feeds 64, 65 is failing, the other one can take over.

FIGS. 5A, 5B, 5C, 5E, 5D, 5E, 5F shows oscilloscope view graphical representations of the load parameter evolution for a PSU of the electrical equipment which is the load parameter at the corresponding output 6 of a PDU module 1. The first PSU 66 is connected to the first 3-phase power source 64 and the second PSU 67 is connected to a second different 3-phase power source 65. The present power distribution system is thus a dual feed system, wherein the rack is provided with two independent power sources 64, 65 and wherein the electrical equipment 61 has two PSU's 66, 67, each one connected with a separate power bar. This dual feed system ensures that the electrical equipment is provided with power substantially all the time. Loss of power from one power source can be backed-up with another power source connected to the same electrical equipment. The power distribution system 60 comprises a gateway controller 22 in one of the power bars. In the embodiment of FIG. 6, the controller is provided in power bar PDU A. The controller 22 is arranged to switch between powering an electrical equipment 61 of the set of electrical equipment with the outlet 68 provided on the PDU A and the outlet 69 provided on PDU B. The switching comprises dividing the power delivery to the electrical equipment between the outlet provided on the first power bar and the outlet provided on the second power bar according to a division scheme which comprises powering the electrical equipment fully by the outlet provided on PDU A, referred to as a primary outlet. This embodiment ensures that a minimal amount of power is wasted by a stand-by outlet. This could of course lead to a redundancy risk. This is in the current invention controlled by providing a fast switching of a failed or failing outlet to a working outlet on the power bar PDU B. Some embodiments of the invention comprise switching to powering the electrical equipment fully by the outlet of PDU B, which could be seen as a kind of back-up outlet, upon detecting the failure of the primary outlet. In an embodiment all the outlets of PDU A are primary outlets and all of the outlets of PDU B are back-up outlets. In order to realize a very fast switching, the PDU A and PDU B are directly connected to each other by means of a data connection 20 implemented in the embodiment of FIG. 6 as a data cable. The data connection 20 between the two power bars 62, 63 increases the speed by which the controllers 17, 22 can switch the outlets powering the electrical equipment 31. The data connection 20 avoids having to transmit a signal from the first power bar to the second power bar over an external network route. By not going over an external network route, also cybersecurity is simultaneously increased. As stated above, the gateway controller 22 is in the gateway module 12 provided in PDU A only, i.e. not in both PDU A and PDU B. Therefore, a controller for PDU B is omitted in the embodiment of FIG. 6. This is illustrated on FIG. 6 by a gateway module without controller. This results in a cheaper redundant power distribution system.

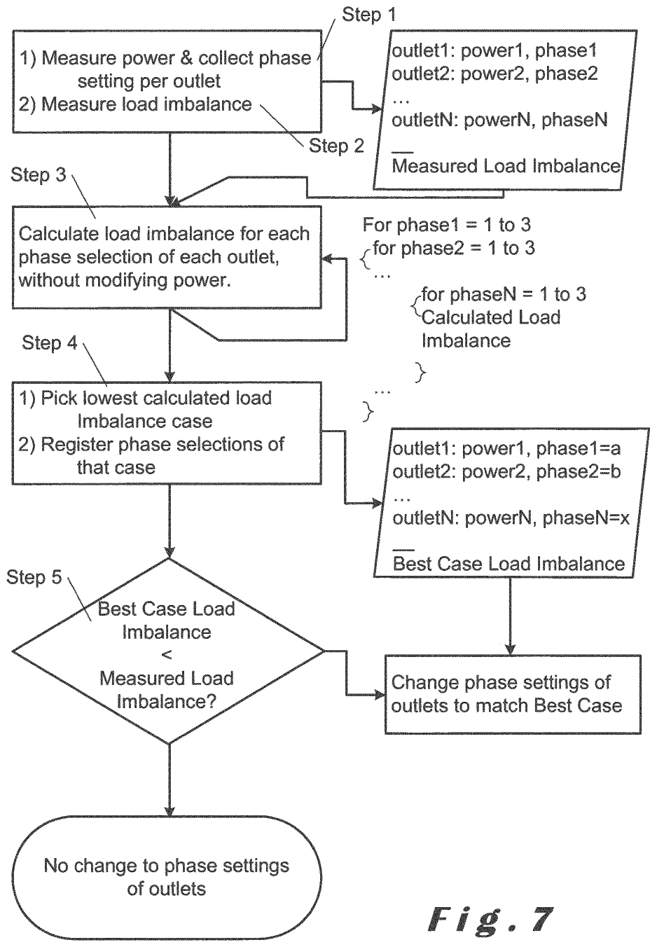

In an embodiment of the invention, the power distribution system 60 is configured to minimize the load imbalance between the live lines of the three-phase power feeds. In three phase systems, current imbalance is for example the maximum deviation of any phase current from average divided by the average current. As electrical equipment connected to the power distribution system 60 are single-phase loads, imbalance may occur due to unequal distribution of single-phase loads over the three phases. FIG. 7 illustrates a flow chart of a load imbalance algorithm that may be executed by the controller 22 of the power distribution system 60.

At a first step, for each outlet, the controller calculates the power based on the measurements received from the voltage sensors 9 and the current sensors 8 in the power distribution system 60 and the controller 22 registers for each outlet the corresponding phase setting.

At a second step, based on the information of the calculated power consumption and the phase setting for each outlet, the power load imbalance is calculated resulting in a calculated load imbalance. The power load imbalance of a three-phase system may be calculated as the maximum deviation of any phase power from average divided by the average power.

At a third step, the individual power calculations at each outlet are taken through an iterative process, in which the load imbalance is calculated for hypothetical combinations of phase settings. For this, an exhaustive list of all possible combinations of phase settings is obtained by cycling through phase setting 1, 2 and 3, corresponding to live lines 51, 52, 53 in FIG. 4A, for each outlet individually.

At a fourth step, the combination with the lowest calculated load imbalance is selected and labelled as Best Case.

At a fifth step, the load imbalance of Best Case is compared with the calculated load imbalance of the second step. And, if the load imbalance of Best Case is lower than the calculated load imbalance (the “yes” situation), the controller is sending instructions to the phase switches 29 to set the phase settings to the phase settings of Best Case. If however the load imbalance of Best Case is not lower than the calculated load imbalance (the “no” situation), no change is made.

By executing this method in the power distribution system, the load imbalance is minimized and the power is used in the most effective way. The result is that a rack being executed with this power distribution system 60 is consuming less energy.

This method of imbalance correction may be executed by a power distribution system having one power bar and one power feed for this power bar as well as by a power distribution system having two power bars and two power feeds for these two power bars.

These power distribution systems may monitor the power consumption on a per outlet basis continuously. In an embodiment of the invention, the above-described power imbalance correction may be executed once a day on a set time.

In a power distribution system having two power bars for providing power to electrical equipment with two PSUs, the imbalance correction is executed for the outlets of both power bars but the controller may be configured to execute the imbalance correction for each power bar at a different point in time. This ensures that an electrical equipment is never having a power cut because always one of the two PSUs is connected to a power source. In an alternative embodiment of the invention, the controller may be configured to execute the imbalance correction of all outlets of the two bars together and to switch two outlets connected to two PSUs of an electrical equipment, such as a server, at a different point in time. This ensures similar as in previous embodiment that an electrical equipment is never having a power cut because always one of the two PSUs is connected to a power source.

By permanently equalizing power consumption over the three phases, the power headroom is maximized and stranded capacity is eliminated. At the same time, upstream heat losses are reduced.

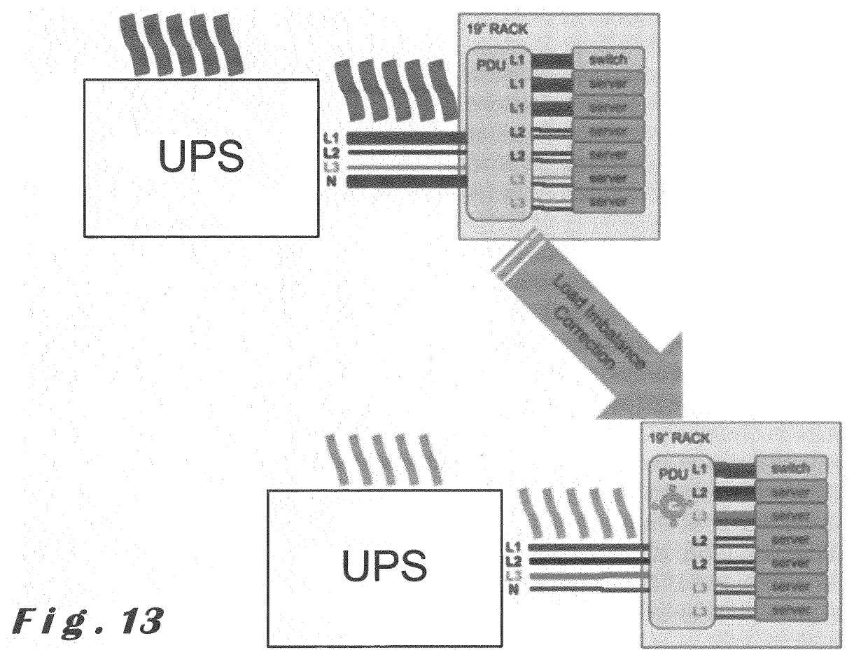

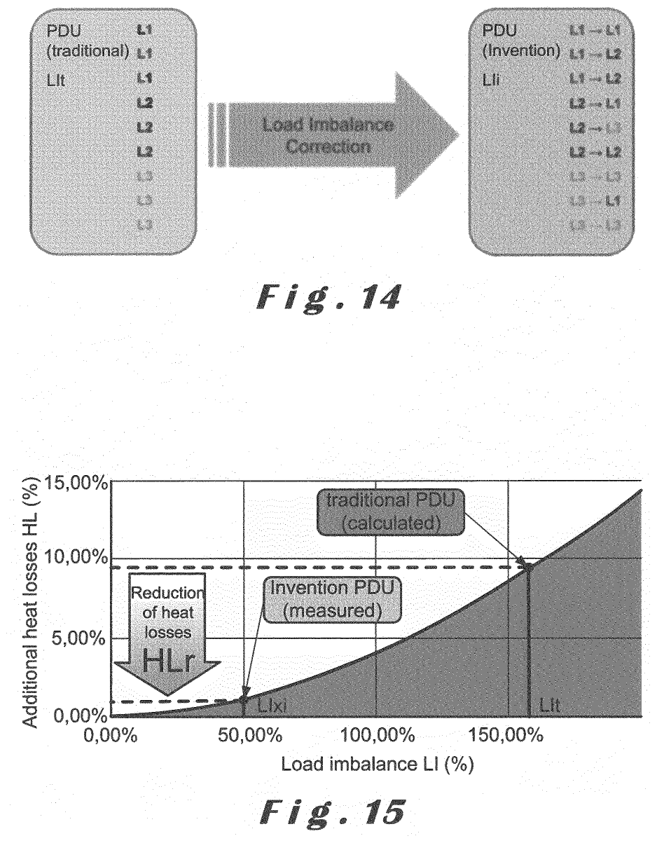

FIGS. 13, 14 and 15 illustrate the difference in heat loss between a traditional system without imbalance correction and a system according to embodiments of the invention with imbalance correction. The reduction of heat losses (HLr) can be defined as the difference between the heat losses induced by the load imbalance of a hard-wired traditional power distribution system (HLt) and a power distribution system according to an embodiment of the invention with imbalance correction (HLi).

$$HLr = HLt - HLi$$

Measurements learn that the load imbalance can be improved from a load imbalance of above 150% to 50% by using a power distribution system according to an embodiment of the invention which is executing the imbalance correction method according to an embodiment of the invention. This reduction in imbalance corresponds with a reduction in upstream heat losses from about 10% to about 1% as shown in FIG. 15.

FIG. 2 illustrates the releasably mounting of a PDU module 1 to the frame 3 according to an embodiment of the invention. Once assembled, the frame comprises slots to receive the modules. The to be mounted PDU module 1 is to be positioned in the slot such that the contact pins 25, shown on FIG. 9, mate with the contact pin receivers 23 and the data connector 26 mates with the data connector receiver 27.

The contact pins 25 connected to the contact pin receivers 23 transfer electrical AC power which may be bidirectional. The data connector 26 connected to the data connector receiver 27 transfers on the one hand DC power from the backbone, i.e. the assembled frame without modules inserted to it, to the module 1, 12 and is on the other hand configured for bidirectional data communication from and to the module.

The modules, PDU module 1 and/or Gateway module 12, are releasably mounted to the frame via a snap mechanism. When the module is brought into position, snaps are locking the module in the correct position.

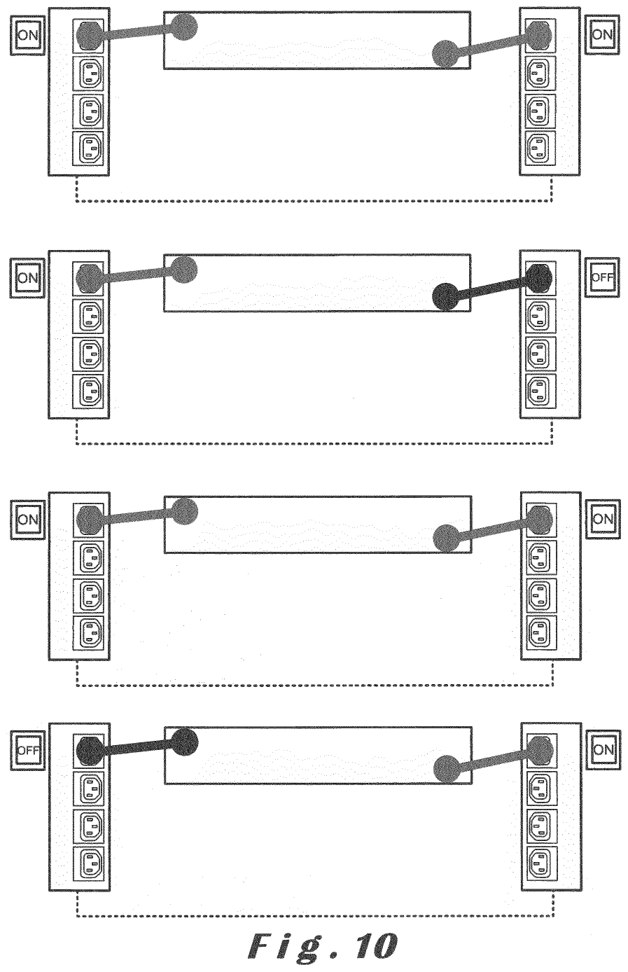

In an embodiment of the invention, the power distribution system 60 is configured to save energy consumed by two-PSU servers. This is realized by executing the following method:
In a first step all PSUs are connected for a first predetermined time. The first predetermined time is preferably between 10 and 50 minutes, more preferably between 20 and 40 minutes and most preferred 30 minutes. The controller 22 is sending instructions to the micro-controllers 17 in the different modules 1 to set all decoupling parts 16 of the phase switches 29 in a closed status. This is illustrated in FIG. 10 where a two-PSU server in shown in 4 different statuses of the decoupling switches 16. After step one, the two-PSU server is in the status on top of FIG. 10 with both sides the decoupling switch in the ON status.
In a second step, power consumption measurements are made for each outlet and power signals of each outlet and thus also for each PSU are received by the micro-controllers 17 in the PDU modules.
In a third step, the micro-controllers 17 are executing a sanity check on the power signals of all PSUs by applying power quality measurement definitions of a standard as there is, but not limited to, IEEE1159-1995, to the signals of all PSUs. This sanity check is executed because, if all PSUs are categorized as ‘healthy’, the server power requirements will not be compromised by disconnecting PSUs. A PSU is assumed healthy by registering its signals when entering first operation, which the operator sentiently confirms.
In a fourth step, one of the two PSUs of each two-PSU server is disconnected for a second predetermined time. The second predetermined time is preferably between 15 and 30 hours, more preferably between 20 and 25 hours and most preferred 23 hours 30 minutes. This is illustrated by the second status in FIG. 10, the right PSU is in the OFF status and the left PSU in in the ON status.
In a fifth step, once the second predetermined time is over, the first, second and third step is performed again. This includes the third status of two-PSU servers shown in FIG. 10, both PSUs are again in the ON status.
In a sixth step, the fourth step is performed again but now the other one of the two PSUs of each two-PSU server is disconnected for the second predetermined time. This is the fourth status in FIG. 10 where the left PSU is in the OFF status and the right PSU is in the ON status.

This method can be performed continuously until a sanity check determines a PSU which is unhealthy.

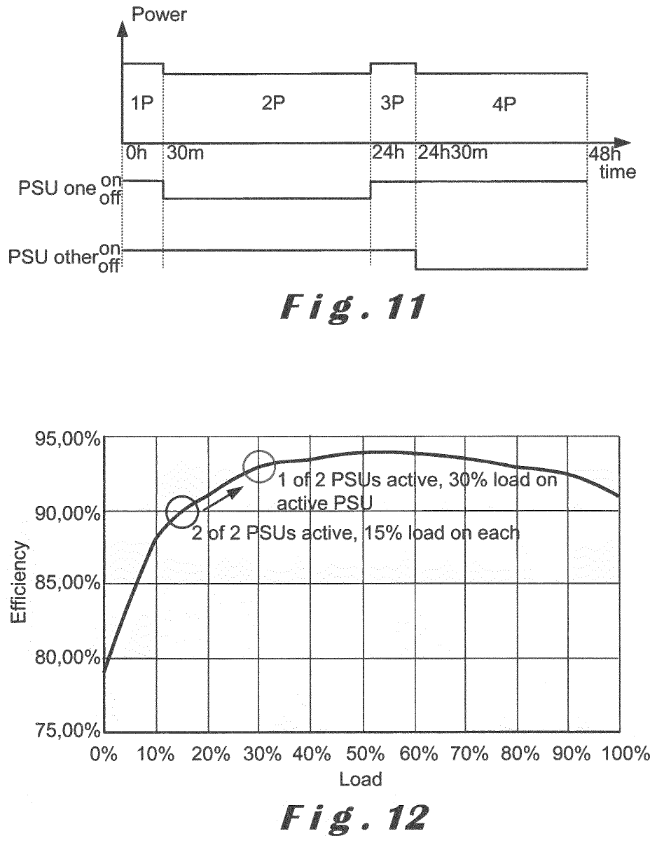

The advantage of controlling the power sent to the PSUs of two-PSU servers according to the steps above is that this results in a lower power consumption by each two-PSU server. This is illustrated in FIG. 11 which is showing the power consumption at both PSUs and the combined power consumption over a period of 48 hours for an embodiment wherein the first and second predetermined time have the most preferred value, i.e the first predetermined time is 30 minutes and the second predetermined time is 23 hours 30 minutes. In the first 30 minutes, both PSUs are connected and the power consumption is at a level as illustrated is segment 1P. After 30 minutes the power consumption is going down corresponding to the fourth step in above method. One of the two PSUs is disconnected and the power consumption is lower, as illustrated in segment 2P. After the second predetermined time of 23 hours 30 minutes, the PSUs are again both connected to the power source corresponding to the sixth step in above method because both PSUs are again for 30 minutes connected to the power sources. This is illustrated by segment 3P in FIG. 11. After this predetermined time of 30 minutes of segment 3P in FIG. 11, thus in total after 24 hours 30 minutes, the other of the two PSUs is now disconnected from the power source and the power consumption is going down again for 23 hours 30 minutes corresponding to the sixth step in above method. This is illustrated by segment 4P in FIG. 11.

FIG. 12 illustrates the efficiency of a PSU on the Y-axis of the graph for each percentage of load on the x-axis. The graph illustrates that the efficiency of a PSU is varying based on the percentage of load and that the efficiency is increasing by increasing the load in the section between 0% up to about 50%. Knowing that PSUs are normally not operating above 50% load, mostly in the section 10% to 30%, in the above method illustrated in FIG. 11, the power supply that remains connected to the power source is pushed to a higher efficiency by transferring the load of the PSU that is disconnected from the power source. As illustrated in FIG. 12, assume that the load percentage of both PSUs is at 15% when both PSUs are connected to the power sources, by disconnecting one the PSU, the load will increase from 15% to 30% which will result in an efficiency increase from 90% to 93%.

Furthermore, by executing the above method, there is the additional advantage that the circuitry and the fans of a disconnected PSU are not consuming energy too.

This method can be extended to servers with more than two PSUs. In this case, at least two PSUs can be left active, one on each power feed, thus keeping redundancy unchanged.

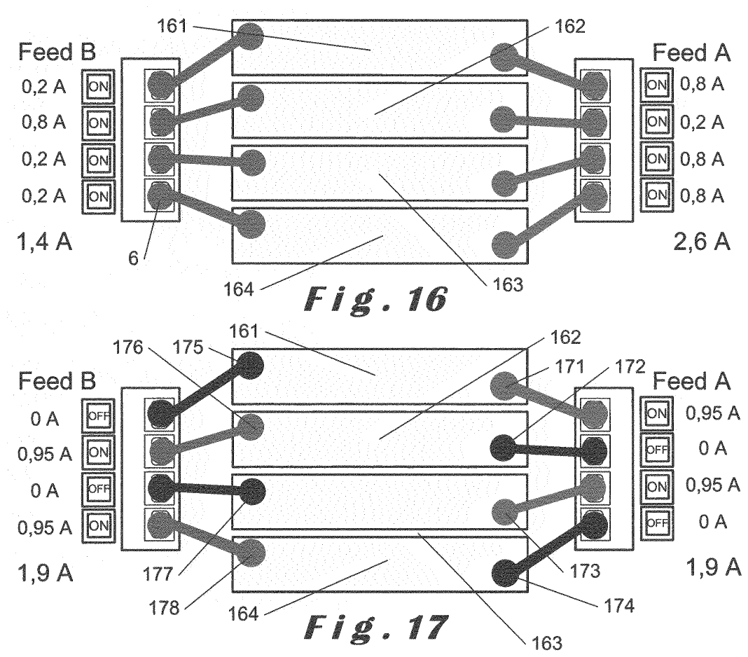

FIGS. 16, 17, 18 and 19 illustrate a method for failure checking according to an embodiment of the invention to prevent downtime by an emergency switch-on of a disconnected PSU based on power quality phenomena monitoring.

In FIG. 16, four two-PSU servers 161, 162, 163, 164 are shown, all connected to the two power feeds. Thus, the four PSUs on the right side are connected to power feed A and the four PSUs on the left side are connected to power feed B. For all outlets 6 connected to the PSUs, the decoupling part 16 of the phase switch 29 is closed and thus all PSUs are in an ‘ON’ status as shown in FIG. 16. In this situation, the dual-PSU servers do not balance power consumption evenly over their PSUs. The right PSUs are consuming 0.8 A while the left PSUs are consuming 0.2 A. The result is that one of the two PSUs of each server is not running efficiently.

As illustrated in FIG. 17, in the same configuration of FIG. 16, a number of PSUs may be disconnected from the power feeds by opening the decoupling part 16 of a number of the phase switches 29. When the decoupling part 16 is open and the PSU is thus not connected to the power feed, the ‘OFF’ status is shown in FIG. 17. For two-PSU server 161, the left PSU 175 is set in ‘OFF’ status while the right PSU 171 is maintained in the ‘ON’ status. For server 162, the left PSU 176 is in the ON status and the right PSU 172 is in the OFF status. For server 163, the left PSU 177 is in the OFF status and the right PSU 173 is in the ON status. For server 164, the left PSU 178 is in the ON status and the right PSU is in the OFF status. By disconnecting one of the two PSUs of a dual-PSU server, the power consumption of the PSU which remains connected is increasing to 0.95 A. As shown in FIG. 17, by dividing the PSUs in the ON status over the two power feeds A and B, at both power feeds there is a total consumption of 1.9 A. Comparing this to the situation in FIG. 16 where all PSUs are in the ON status, by disconnecting one of the two PSUs of a dual-PSU server, a 5% energy consumption reduction is realized.

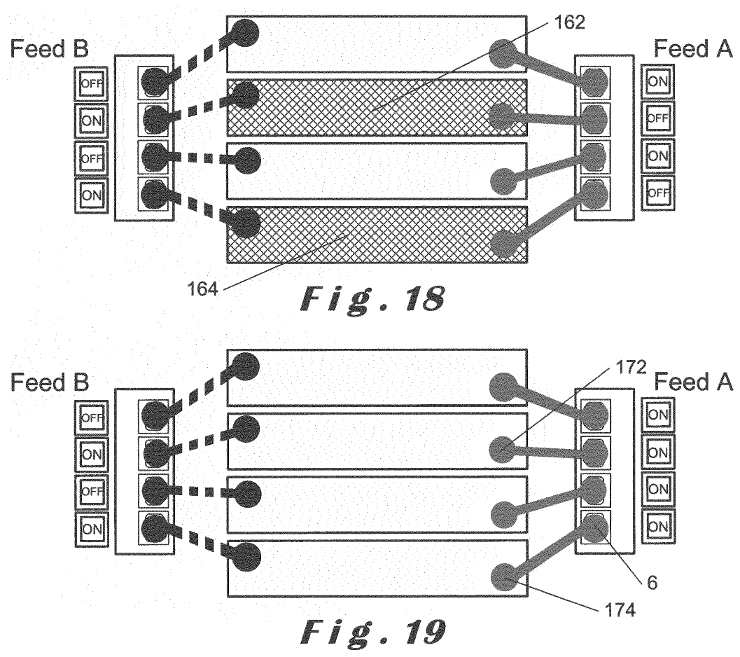

Operating dual-PSU servers with only one of the two connected to a power source creates however the risk that the server will have no power if one of the two power feeds fails. In FIG. 18 illustrates the situation of FIG. 17 when power feed B fails. In that situation servers 162, 164 are no longer connected to a power source.

To avoid the situation of FIG. 18, in an embodiment of the invention, power quality measurements are executed such that an emergency switch-on of PSUs 172 and 174 can be executed by closing the decoupling parts 16 of the phase switches 29 in the corresponding outlets 6 as shown in FIG. 19.

For power quality measurements, the power quality definition of IEEE 1159-1995 may be used:

| Categories | Typical Duration | | Typical Magnitude | |
|---|---|---|---|---|
| 2.1 Instantaneous | | | | |
| 2.1.1 Sag | 0.5-30 | cycles | 0.1-0.9 | pu |
| 2.1.2 Swell | 0.5-30 | cycles | 1.1-1.8 | pu |
| 2.2 Momentary | | | | |
| 2.2.1 Interruption | 0.5-3 | seconds | <0.1 | pu |
| 2.2.2 Sag | 0.5-3 | seconds | 0.1-0.9 | pu |
| 2.2.3 Swell | 0.5-3 | seconds | 1.1-1.8 | pu |

| | | | |
|---|---|---|---|
| 2.3 Temporary | | | |
| 2.3.1 Interruption | 3 sec-1 minute | <0.1 | pu |
| 2.3.2 Sag | 3 sec-1 minute | 0.1-0.9 | pu |
| 2.3.3 Swell | 3 sec-1 minute | 1.1-1.8 | pu |

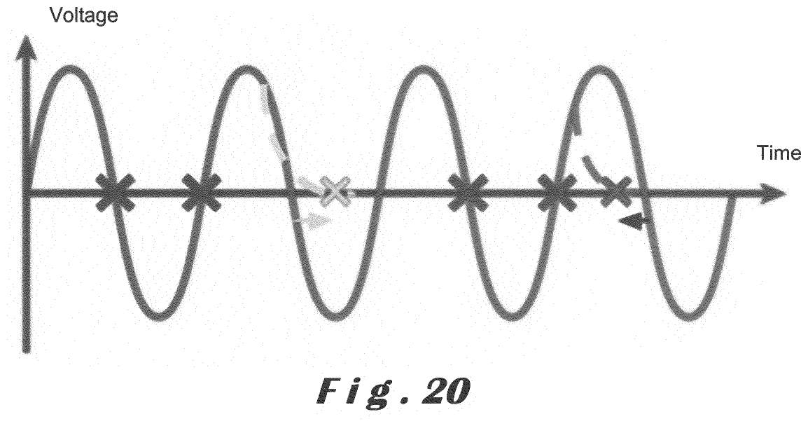

In an embodiment of the invention the IEEE definitions for power quality measurements may be applied to current, total harmonic distortion and power factor to create triggers. These quality measurements are executed by the micro-controllers 17 in the PDU module. When the controller 17 determines a trigger, the micro-controller 17 instructs the outlets of the power feed which is ‘healthy’ to close all decoupling parts of the PSUs which are in OFF status. As a result, the servers are brought in the situation of FIG. 19 before a power feed fails, i.e. all PSUs in ON status at the healthy power feed. A trigger may be a too high total harmonic distortion. Another trigger may be current swells, sags and interruptions. Still another trigger may be power factor sags. Another trigger may be the detection of a deviation of the expected zero-crossing time of the voltage. This is illustrated in FIG. 20. FIG. 20 illustrates the AC voltage curve over time. The curve of the AC voltage has a zero-crossings 201 which are expected every 10 ms for 50 Hz or 8.33 ms for 60 Hz, and has an extremely low jitter. In FIG. 20, the zero-crossings 201 are zero-crossings in normal operation. The zero-crossing may be detected later in time than expected as illustrated with zero-crossing 202. The zero-crossing may be detected earlier in time than expected as illustrated with zero-crossing 203. Both, a delayed zero-crossing 202 or an earlier zero-crossing 203 are triggers for a power loss. When such trigger is detected, an instruction is transmitted to the controller of the outlets of the alternate, healthy power feed to set all outlets in the ON status. This prevents that multi-feed servers are disabled when operating in energy saving modus with one of the two PSUs decoupled from a power feed.

1. A computer-implemented method for distributing three-phase power in a rack system wherein the rack system comprises a power distribution system for powering electrical equipment and configured to be fed with a three-phase power source, the power distribution system comprising at least one power bar comprising at least three outlets, power sensors for measuring the voltage and current of each outlet, and phase switches for switching the live lines of the outlets, the method comprising
receiving the voltage and current value of each outlet,
calculating the power of each outlet based on the received voltage and current values,
registering the calculated power for each outlet and the corresponding phase setting,
calculating the power load imbalance based on the calculated power and the phase setting of each outlet resulting in a calculated load imbalance,
calculating individual power calculations at each outlet through an iterative process, in which the load imbalance is calculated for hypothetical combinations of phase settings,
selecting the hypothetical combination with the lowest load imbalance as Best Case,
comparing the load imbalance of Best Case with the calculated load imbalance, and
if the load imbalance of Best Case is lower than the calculated load imbalance, sending instructions to the phase switches to set the phase settings to the phase settings of Best Case.

2. A power distribution system comprising a processor configured to perform the method of claim 1.

3. A computer program comprising instructions which, when the program is executed by a computer, cause the computer to carry out the steps of the method of claim 1.

4. A computer-implemented method for distributing power in a rack system wherein the rack system comprises a power distribution system for powering multi-PSU electrical equipment and is fed with at least two power sources, the power distribution system comprising at least two power bars comprising at least one outlet, power sensors for measuring the voltage and current signals of each outlet, and decoupling switches for switching the live line towards an outlet on or off, the method comprising
receiving the voltage and current signals of each outlet,
applying power quality measurements on the received signals to determine triggers for a power fail,
if a trigger for a power fail is determined for an outlet connected to a multi-PSU equipment, determining another outlet connected to the multi-PSU equipment, and
transmitting an instruction to the other outlet to switch the decoupling switch to the on status.

5. A power distribution system comprising a processor configured to perform the method of claim 4.

6. A computer program comprising instructions which, when the program is executed by a computer, cause the computer to carry out the steps of the method of claim 4.

7. A power distribution unit (PDU) module for distributing power to electrical equipment such as servers and network switches arranged in a data center rack, the PDU module comprising:
an input configured to be coupled to a power source to receive 3-phase power from the power source;
a plurality of power lines coupled to the input, the power lines being configured to carry the 3-phase power and wherein the power lines comprise three live lines and one neutral line;
multiple outlets each one coupled to at least two of the plurality of power lines such as to receive power from one of the three phases of the 3-phase power by connecting to one of the three live lines and the neutral line, each outlet being configured to be coupled to an electrical equipment such as to power the electrical equipment, wherein each outlet is provided with at least one power sensor configured to sense a parameter of the power supplied to the at least one outlet;
wherein the PDU module is configured to be connected to a gateway controller such that the gateway controller is in connection with the at least one power sensors, and
wherein the PDU module further comprises at least one three-phase switch and at least one decoupling switch, wherein the at least one three-phase switch is configured to selectively couple the phase contact of each outlet to one of the three live lines, and
wherein the at least one decoupling switch is configured to selectively decouple the phase contact of each outlet from the live lines.

8. The PDU module according to claim 7, wherein one three-phase switch is provided for each outlet such as to select the live line connected to each outlet.

9. The PDU module according to claim 7, wherein one three-phase switch is provided for a group of outlets such as to select the live line connected to the group of outlets.

10. The PDU module according to any one of the claims 7 to 9, wherein one decoupling switch is provided for each outlet such as to decouple each outlet from the live lines.

11. The PDU module according to any one of the claims 7 to 10, wherein the parameter measured by the power sensor of the outlet is indicative of the load on the outlet, further referred to as the load parameter, wherein preferably the load parameter is the current drawn by the outlet, and wherein the controller is configured to monitor the load parameters of the outlets within the PDU module and further configured to create instructions to operate the at least one three-phase switch and the at least one decoupling switch based on the monitored load parameters and wherein the PDU module is configured to receive the instruction from the gateway controller to control the three-phase switch and the decoupling switch.

12. The PDU module according to claim 11, wherein the controller is configured to determine based on the load parameters, the total loads on each phase, and wherein the controller is further configured to create instructions to operate the at least one three-phase switch and the at least one decoupling switch such as to increase the load balance of the three phases and wherein the PDU module is configured to receive the instruction from the gateway controller to control the three-phase switch and the decoupling switch.

13. The PDU module according to any one of the claims 7 to 12, wherein the controller is configured to maintain a list of outlets, the phase delivered to said outlets and the load parameter of the outlets, and wherein the controller is further configured to use the list to determine which outlets should switch phase and wherein the controller is configured to create instructions to operate the three-phase switch accordingly.

14. The PDU module according to any one of the claims 7 to 13, wherein the controller is configured to determine the highest loaded phase and the lesser loaded phases, and to use the list to determine which outlets should switch from the highest loaded phase to one of the lesser loaded phases.

15. The PDU module according to any one of the claims 7 to 14, wherein the list further comprises the priority of the outlets indicating the importance of reliable operation of the outlets.

16. The PDU module according to any one of the claims 7 to 155, wherein the controller is configured to receive via the data connector, phase loading information related to the loading of the three phases of at least one external device coupled to the power source, and further configured to operate the at least one phase switch additionally based on the received phase loading information.

17. The PDU module according to any one of the claims 7 to 16, wherein the power sensor is enabled to sample the parameter at microsecond level, and wherein the controller is adapted to enable oscilloscope view graphical representation of the parameter in time domain and/or frequency domain comprising representation of the parameter's harmonics.

18. The PDU module according to any one of the claims 7 to 17 wherein the controller is arranged to identify abnormalities in the time domain and/or frequency domain representation of the parameter.

19. The PDU module according to any one of the claims 7 to 18 wherein the controller is arranged to compare the measured parameters to reference data retrieved from a cloud where the measured parameters of the PDU module and preferably from other PDU modules are stored such as to allow to identify abnormalities in the time domain and/or frequency domain representation of the parameter based on machine learning.

20. The PDU module according to any one of the claims 7 to 19 wherein the parameter measured by the power sensor is the current delivered to the output, and wherein the input of the PDU module further comprises a voltage sensor arranged to measure the voltages between the power lines at microsecond level, and wherein the controller is adapted to enable oscilloscope view graphical representation of the voltages in time domain and/or frequency domain comprising representation of the parameter's harmonics.

21. A power bar comprising an elongated frame arranged to be mounted to a data center rack in a vertical 0 U or in a horizontal 1 U configuration, the power bar further comprising at least one PDU module according to any one of the preceding claims 7 to 21 mounted on the frame.

22. The power bar according to claim 21 wherein the at least one PDU module is releasably mounted on the frame, thereby forming a modular power bar.

23. The power bar according to any one of the claims 21 to 22 wherein the power bar further comprises at least one network switch module having a plurality of network ports, the at least one network switch module being releasably mounted on the frame.

24. The power bar according to any one of the claims 21 to 23, wherein the power bar comprises multiple PDU modules.

25. The power bar according to any one of the claims 21 to 24, wherein the controller is mounted on the power bar.

26. The power bar according to any one of the claims 21 to 25, wherein the frame comprises a power inlet connected to the power source, and wherein the modules mounted to the frame receive power from the power inlet.

27. The power bar according to any one of the claims 21 to 26, wherein the frame comprises a power bus, and wherein the modules mounted on the frame connect to the power bus such as to transfer power from the power bus to the modules.

28. A power distribution system for powering multi-PSU ICT equipment, comprising a first power bar according to any one of the preceding claims 21 to 27 arranged to couple multi-PSU ICT equipment to a first 3-phase power source, and a second power bar according to any one of the preceding claims 21 to 27 arranged to couple the same multi-PSU ICT equipment to a second 3-phase power source, wherein the multi-PSU ICT equipment comprises two physically distinct power inlets wherein the first power inlet is connected to the first 3-phase power source and the second power inlet is connected to the second 3-phase power source.

29. The power distribution system according to the preceding claim wherein the system comprises a gateway controller arranged to switch between powering a multi-PSU ICT equipment with the outlet provided on the first power bar and the outlet provided on the second power bar.

30. The power distribution system according to the preceding claim wherein the switching comprises dividing the power delivery to the multi-PSU ICT equipment between the outlet provided on the first power bar and the outlet provided on the second power bar according to a division scheme.

31. The power distribution system according to the preceding claim wherein the division scheme comprises powering the electrical equipment fully by the outlet provided on one of the first power and the second power bar, referred to as a primary outlet, and switching to powering the electrical equipment fully by the outlet of the other one of the first power bar and the second power bar, referred to as a back-up outlet, upon detecting the failure of the primary outlet.

32. The power distribution system according to the preceding claim wherein all the outlets of the first power bar are primary outlets and wherein all of the outlets of the second power bar are back-up outlets.

33. The power distribution system according to any one of the preceding claims 28 to 32 wherein the first power bar and the second power bar are directly connected by means of a data connector, preferably a data cable such as to increase the speed by which the controller can switch the outlets powering the ICT equipment.

34. The power distribution system according to the preceding claim, wherein the gateway controller is provided in one of the first power bar or the second power bar.
